(19) United States
(12) Patent Application Publication
(10) Pub. No.: US 2025/0336906 A1
(43) Pub. Date: Oct. 30, 2025

(54) Stacked Chip Assemblies for Display Systems

(71) Applicant: Apple Inc., Cupertino, CA (US)

(72) Inventors: Bilin Wang, San Jose, CA (US); Kanghoon Jeon, San Jose, CA (US); Denis M. Darmon, Boulder, CO (US); Kunzhong Hu, Cupertino, CA (US); Pablo Moreno Galbis, Burlingame, CA (US); Chonghua Zhong, Cupertino, CA (US); Chun-Yao Huang, San Jose, CA (US); Hopil Bae, Sunnyvale, CA (US); Martin R. Kardasz, Mountain View, CA (US); Stanley B. Wang, Cupertino, CA (US); Bruce C. Gamache, Boulder, CO (US); Abhinava Kumar, San Diego, CA (US); Johan L. Piper, Cupertino, CA (US)

(21) Appl. No.: 19/090,076

(22) Filed: Mar. 25, 2025

Related U.S. Application Data
(60) Provisional application No. 63/638,273, filed on Apr. 24, 2024.

(51) Int. Cl. H01L 25/18; H01L 23/00; H01L 23/498; H01L 23/538; H04N 9/31; H10D 86/40; H10D 86/60; H10H 29/39; H10H 29/45; H10K 59/123; H10K 59/127; H10K 59/131

(52) U.S. Cl. CPC H01L 25/18; H01L 23/49822; H01L 23/49838; H01L 23/5383; H01L 23/5386; H01L 23/5389; H01L 24/08; H01L 24/16; H10D 86/441; H10D 86/60; H10H 29/39; H10H 29/45; H01L 2224/08146; H01L 2224/16235; H01L 2924/1426; H04N 9/3164; H10K 59/123; H10K 59/1275; H10K 59/131

(57) ABSTRACT

A stacked chip assembly for a display system may include a front plane die and one or more backplane dies, such as a first backplane die and a second backplane die. The front plane die may include a plurality of light emitting diodes (LEDs). The one or more backplane dies may be stacked vertically relative to the front plane die. In some implementations, the first backplane die may include a first portion of metal oxide semiconductor field effect transistor (MOSFET) display circuitry coupled with the plurality of LEDs, and the second backplane die may include a second portion of MOSFET display circuitry coupled with the first portion of MOSFET display circuitry. In some implementations, the backplane die may include display circuitry that is partitioned between analog circuitry in a first layer and digital circuitry in a second layer. Other aspects are also described and claimed.

### RELATED APPLICATIONS

This patent application claims the benefit of priority of U.S. Provisional Application No. 63/638,273, filed Apr. 24, 2024, which is incorporated herein by reference in its entirety.

### BACKGROUND

### Field

This disclosure relates generally to display systems and, more specifically, to stacked chip assemblies for display systems. Other aspects are also described.

### Background Information

State of the art displays for portable electronics, computers, and televisions commonly utilize glass substrates with thin film transistors (TFTs) to control transmission of backlight through pixels based on liquid crystals. More recently emissive displays such as those based on organic light emitting diodes (OLEDs) have been introduced. Even more recently, it has been proposed to integrate emissive inorganic semiconductor-based micro LEDs into displays. In either implementation, the LEDs are commonly either formed over a display panel including pixel circuitry for driving the LEDs or the LEDs are transferred to such a display panel.

### SUMMARY

Implementations of this disclosure include configurations of vertically stacked chip assemblies having a front plane die including LEDs and a separate backplane die including metal oxide semiconductor field effect transistor (MOSFET) display circuitry. The front plane die and the backplane die may separate circuitry in the different chips based on closeness to the active array of LEDs. Further, in some cases, the backplane die can implement analog and digital circuitry in separate layers of the chip. This may enable lighting in display systems having a reduced size or compact form factor. This may also enable higher resolution of display systems via more pixels arranged closer together. This may also enable more efficient manufacturing of the display systems, such as group transfers of die to die or die to wafer, which can be accomplished using fabrication techniques such as wafer-on-wafer (WoW) bonding, chip-on-wafer (CoW) bonding, flip chip bonding, and/or combinations thereof.

In some implementations, a stacked chip assembly for a display system may include a front plane die and one or more backplane dies, such as a first backplane die and a second backplane die. The front plane die may include a plurality of LEDs. The one or more backplane dies may be stacked vertically relative to the front plane die. In some implementations, the first backplane die may include a first portion of MOSFET display circuitry coupled with the plurality of LEDs, and the second backplane die may include a second portion of MOSFET display circuitry coupled with the first portion of MOSFET display circuitry. In some implementations, the backplane die may include display circuitry that is partitioned between analog circuitry in a first layer and digital circuitry in a second layer. Other aspects are also described and claimed.

The above summary does not include an exhaustive list of all aspects of the present disclosure. It is contemplated that the disclosure includes all systems and methods that can be practiced from all suitable combinations of the various aspects summarized above, as well as those disclosed in the Detailed Description below and particularly pointed out in the Claims section. Such combinations may have particular advantages not specifically recited in the above summary.

### BRIEF DESCRIPTION OF THE DRAWINGS

Several aspects of the disclosure here are illustrated by way of example and not by way of limitation in the figures of the accompanying drawings in which like references indicate similar elements. It should be noted that references to “an” or “one” aspect in this disclosure are not necessarily to the same aspect, and they mean at least one. Also, in the interest of conciseness and reducing the total number of figures, a given figure may be used to illustrate the features of more than one aspect of the disclosure, and not all elements in the figure may be required for a given aspect.

FIG. 1 is an exploded view of an example of a display system.

FIG. 2A is an exploded cross-sectional side view of a first example of a stacked chip assembly.

FIG. 2B is a cross-sectional side view of the first example.

FIG. 3 is a cross-sectional side view of a second example of a stacked chip assembly.

FIG. 4 is a cross-sectional side view of a third example of a stacked chip assembly.

FIG. 5 is an example of a block diagram of a display circuitry with the blocks corresponding to each of the two portions.

FIG. 6 is a cross-sectional side view of a fourth example of a stacked chip assembly.

FIG. 7 is an example of analog circuitry in a first layer and digital circuitry in a second layer of a backplane.

### DETAILED DESCRIPTION

Some display systems may have a reduced size or compact form factor despite necessitating a high resolution. For example, a projector for a headset may have a limited size to accommodate comfort of the user. Nevertheless, the headset may still necessitate a high resolution via display panels of the projector to enhance the user's experience. It is therefore desirable to have a lighting system for displays that can accommodate a reduced size or compact form factor while maintaining a high resolution.

Implementations of this disclosure address conditions such as these by utilizing configurations of vertically stacked chip assemblies having a front plane die including LEDs and a separate backplane die including MOSFET display circuitry, such as n-type metal-oxide-semiconductor (NMOS), p-type metal-oxide-semiconductor (PMOS), or complementary metal-oxide-semiconductor (CMOS). The front plane die and the backplane die may separate circuitry in the different chips based on closeness to the active array of LEDs. Further, in some cases, the backplane die can implement analog and digital circuitry in separate layers of the chip. This may enable lighting in display systems having a reduced size or compact form factor. This may also enable a higher resolution of display systems via more pixels arranged closer together. This may also enable more efficient manufacturing of the display systems, such as with group transfers of die to die or die to wafer.

In some implementations, a stacked chip assembly for a display system may include a front plane die (e.g., an upper die or upper package containing a die) and one or more backplane dies (e.g., one or more lower dies or lower packages containing a die) such as a first backplane die and a second backplane die. The front plane die may include a plurality of LEDs forming pixels, such as red, green, and blue (RGB) LEDs forming a color pixel array or color projection, or a single color of LEDs forming a monochrome pixel array or projection or contributing to part of color pixel array or projection. The one or more backplane dies may be stacked vertically relative to the front plane die, such as immediately below the front plane die, coupled with the front plane die via hybrid bonding including metal-metal and dielectric-dielectric bonding (e.g., oxide-oxide bonding) between the dies.

In some implementations, the first backplane die may include a first portion of MOSFET display circuitry coupled with the plurality of LEDs. The second backplane die may include a second portion of MOSFET display circuitry coupled with the first portion of MOSFET display circuitry. The first portion may comprise pixel circuitry to drive pixels in the front plane and memory cells (e.g., capacitors) for storing bits of the pixels. The second portion may comprise support circuitry for the first portion, such as a timing controller (TCON), power management integrated circuit (PMIC), etc. The first portion and the second portion may each utilize MOSFET technology as opposed to TFT technology. The first backplane die may include through silicon vias (TSVs) extending therethrough, enabling connections between the front plane die above and the second backplane die below. In some cases, the second backplane die may also include TSVs extending therethrough. In some cases, the backplane die may include display circuitry (e.g., pixel circuitry to drive the pixels in the front plane, and memory cells for storing bits for the pixels) that is partitioned between analog circuitry in a first layer and digital circuitry in a second layer. As a result, the stacked chip assembly may enable a reduced size or compact form factor of the display system, a higher resolution of the display system via more pixels arranged closer together, and/or more efficient manufacturing of the display system.

Implementations described herein include stacked chip assemblies for display systems. In various implementations, description is made with reference to figures. However, certain implementations may be practiced without one or more of these specific details, or in combination with other known methods and configurations. In the following description, numerous specific details are set forth, such as specific configurations, dimensions and processes, etc., in order to provide a thorough understanding of the implementations. In other instances, well-known semiconductor processes and manufacturing techniques have not been described in particular detail in order to not unnecessarily obscure the implementations. Reference throughout this specification to “one implementation” means that a particular feature, structure, configuration, or characteristic described in connection with the implementation is included in at least one implementation. Thus, the appearances of the phrase “in one implementation” in various places throughout this specification are not necessarily referring to the same implementation. Furthermore, the particular features, structures, configurations, or characteristics may be combined in any suitable manner in one or more implementations.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

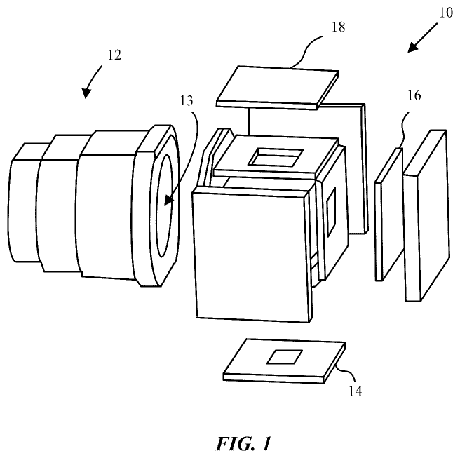

FIG. 1 is an exploded view of an example of a display system 10. The display system 10 may have a reduced size or compact form factor. For example, the display system 10 may comprise a projector for a headset having a limited size to accommodate comfort of a user. The display system 10 may include an eyepiece 12 and a plurality of stacked chip assemblies coupled with the eyepiece, such as stacked chip assemblies 14, 16, and 18, forming display panels. Each stacked chip assembly may include a front plane die including LEDs and one or more backplane dies including display circuitry (e.g., MOSFET, and in some cases, TFT). For example, the stacked chip assembly 14 may include red LEDs to project red light, the stacked chip assembly 16 may include green LEDs to project green light, and the stacked chip assembly 18 may include blue LEDs to project blue light. The plurality of stacked chip assemblies may emit light toward a lens 13 of the eyepiece 12 to form a color projection viewable by a user through the eyepiece 12. In other examples, the stacked chip assemblies 14, 16, and 18 may each include a single, same color of LEDs forming a monochrome projection, or may each comprise LEDs of different colors, such as each stacked chip assembly having RGB LEDs to provide full color. The stacked chip assemblies 14, 16, and 18 may enable lighting in the compact form factor of the display system 10. The stacked chip assemblies 14, 16, and 18 may also enable a higher resolution of the display system 10 via more pixels arranged closer together. The stacked chip assemblies 14, 16, and 18 may also enable a more efficient manufacturing of the display system 10.

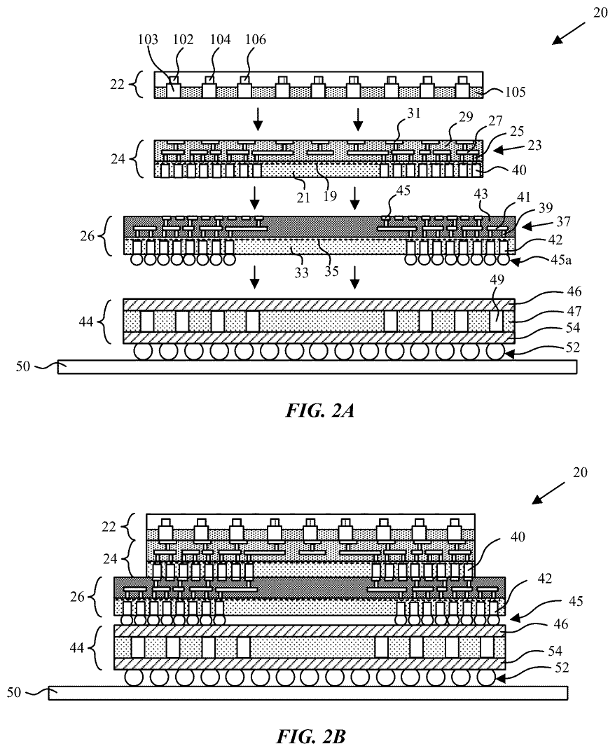

Referring now to FIGS. 2A-2B, cross-sectional side view illustrations are provided of a first example of a stacked chip assembly 20. In interest of clarity, an exploded cross-sectional side view illustration is provided in FIG. 2A to clearly indicate the various stacked dies in the assembly. For example, the stacked chip assembly 20 could be one of the stacked chip assemblies 14, 16, or 18 implemented by the display system 10. The stacked chip assembly 20 may include a front plane die 22 and one or more backplane dies, such as a first backplane die 24 and a second backplane die 26. The front plane die 22 may be an upper die or upper package containing a die of the stacked chip assembly 20 (e.g., upper relative to the one or more backplane dies). The front plane die 22 may include a plurality of LEDs (e.g., 102, 104, 106) forming pixels, such as OLEDs or micro LEDs. Alternatively, the LEDs may be monochromatic, each emitting a same primary wavelength. In the illustrated example, the LEDs are each discrete, physically separate LEDs, though the LEDs May alternatively be separate mesas, connected with a common semiconductor layer. Such a configuration may be used in monochromatic assemblies, or assemblies including groups of monochromatic LEDs. In the illustrated example, backside wiring 103 can be connected to the LEDs to provide electrical backside connections. In the example illustrated, the backside wiring 103 is shown as an array of vias extending through a dielectric layer 105, though the backside wiring 103 can be more complex, including metal redistribution lines, vias, and contact pads, for example, for hybrid bonding with the first backplane die 24.

The first backplane die 24 and the second backplane die 26 may each be lower dies or lower packages containing a die of the stacked chip assembly 20 (e.g., lower relative to the front plane die 22). The first backplane die 24 and the second backplane die 26 may be stacked vertically relative to the front plane die 22, immediately below the front plane die 22. Specifically, the first backplane die 24 may be coupled with the front plane die 22 via hybrid bonding with metal-metal and dielectric-dielectric (e.g., oxide-oxide) bonding between the dies. For example, the plurality of LEDs of the front plane die 22 may connect to the first backplane die 24 via a planar bonding interface using suitable techniques such as WoW or CoW bonding. In such a WoW bonding technique, an LED wafer, such as a III-V wafer or reconstituted wafer, can be hybrid bonded to a wafer (e.g., silicon) including an array of first backplane dies 24. In such a CoW technique, arrays of LED groups can be hybrid bonded to a wafer including the array of first backplane dies 24. Dielectric materials of hybrid bonding may include, for example, silicon oxide, silicon nitride, silicon carbide, or silicon oxycarbide.

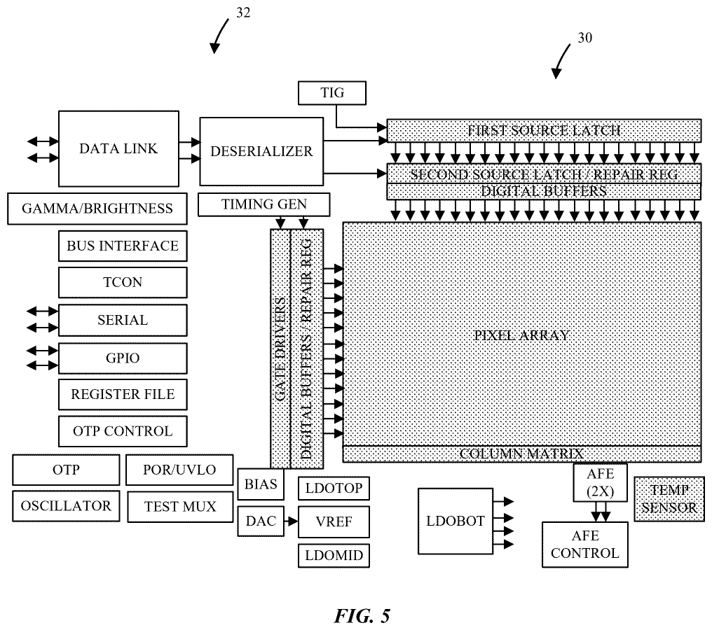

Referring also to FIG. 5, the first backplane die 24 may include a first portion 30 of display circuitry (indicated with shading) coupled with the plurality of LEDs of the front plane die 22. The second backplane die 26 may also include a second portion 32 of display circuitry (indicated without shading) coupled with the first portion 30. The first portion 30 may include, for example, latches, digital buffers, pixel circuitry to drive pixels of the front plane die 22 (e.g., row drivers, column drivers, and/or gate drivers), and/or memory cells for storing bits of the pixels (e.g., capacitors). The second portion 32 may comprise display support circuitry for the first portion 30, such as power, logic, data link, gamma/brightness control, bus interfaces, TCON, PMIC, general purpose I/O (GPIO), register files, one-time programmable (OTP) logic, oscillators, timing generators, serializers/de-serializers, test circuitry, voltage drivers, analog front end (AFE) circuitry, and/or AFE control. Thus, the display circuitry may be partitioned between the first portion 30 and the second portion 32 in the first backplane die 24 and the second backplane die 26, respectively. Due to the vertical stacking of dies there may be a limited number of interconnects that can be supported in each of the dies. Accordingly, the first portion 30 may include the circuitry and interconnects to support the row/column pixel logic. This may involve logic for each LED and pixel, which can involve many connections, and interconnect for hybrid bonding. In order to alleviate the number of interconnects involved per die, the support circuitry associated with the second portion 32 may be allocated to the second backplane die 26 where fewer connections may be required. Additionally, the first portion 30 and/or the second portion 32 may utilize MOSFET technology.

Referring back to FIGS. 2A-2B, the first backplane die 24 may include a first semiconductor substrate 21 (e.g., silicon), a first plurality of TSVs 40 extending therethrough, and a device layer 19 formed in the semiconductor substrate 21, the device layer including various devices (e.g., transistors, etc.) to support the pixel logic. The first plurality of TSVs 40 may enable electrical connections on both sides of the first backplane die 24, between the front plane die 22 above and the second backplane die 26 below. A backside redistribution layer can optionally be formed on the bottom side of the semiconductor substrate 21 and the first plurality of TSVs 40. A back-end-of-the-line (BEOL) build-up structure 23, including a plurality of vias 25, redistribution lines 27, dielectric layers 29, and contact pads 31, can be formed over the semiconductor substrate 21. The contact pads 31 can be metal-metal bonded with the backside wiring 103 of the front plane die 22, and an uppermost dielectric layer of the first backplane die 24 (e.g., the dielectric layer 29) can be bonded with a bottom most dielectric layer of the front plane die 22 (e.g., the dielectric layer 105), in a hybrid bonded configuration.

The second backplane die 26 may also include a second semiconductor substrate 33 (e.g., silicon), a second plurality of TSVs 42 extending therethrough, and a device layer 35 formed in the semiconductor substrate 33, the device layer including various devices (e.g., transistors, etc.) to support the display support circuitry. The second plurality of TSVs 42 may enable electrical connections on both sides of the second backplane die 26, between the first backplane die 24 above and an interposer 44 below. A backside redistribution layer can optionally be formed on the bottom side of the semiconductor substrate 33 and the second plurality of TSVs 42. A BEOL build-up structure 37 including a plurality of vias 39, redistribution lines 41, dielectric layers 43, and contact pads 45 can be formed over the semiconductor substrate 33. The contact pads 45 can be metal-metal bonded with the first plurality of TSVs 40 (or backside redistribution layer) of the first backplane die 24, and an uppermost dielectric layer (e.g., the dielectric layer 43) of the second backplane die 26 can be bonded with a bottom most dielectric layer of the first backplane die 24, in a hybrid bonded or micro bump bond configuration. For example, this can be a native oxide layer, or part of a backside redistribution layer, of the first backplane die 24.

The interposers in accordance with embodiments can be a variety of interposers including both rigid and flexible structures, cored or coreless, and/or formed out of a variety of materials such a glass, silicon, FR4 etc. In FIGS. 2A-2B, the interposer 44 includes a base substrate 47, such as glass, silicon, etc., with electrical connections and routing. For example, this may include vertical interconnects 49 through the base substrate 47, as well as a first redistribution layer (RDL) 46 on top of the base substrate 47, and a second RDL 54 underneath the base substrate 47. The second backplane die 26 may couple with the interposer 44 via a plurality of micro bumps 45a (e.g., the die stack may be flipped onto the interposer 44). Specifically, the plurality of micro bumps 45a may attach the second plurality of TSVs 42 (or contact pads of a backside RDL of the second backplane die 26) with contact pads of the first RDL 46 of the interposer 44. The second portion 32 of the display circuitry, implemented by the second backplane die 26, may couple with the interposer 44 via the plurality of micro bumps 45a. As described herein, micro bumps may utilize more conventional assembly techniques, while hybrid bonding may utilize the metal-metal and dielectric-dielectric (e.g., oxide-oxide) bonding to achieve a higher connection density, a lower latency, and a smaller z-height.

The first RDL 46 may be included to relax pad pitch between the second backplane die 26 and the interposer 44. The interposer 44 may be stacked vertically relative to the front plane die 22, the first backplane die 24, and the second backplane die 26, and may provide mechanical strength for the stacked chip assembly 20, such as to compensate for thinning of the first backplane die 24 and the second backplane die 26. The interposer 44, in turn, may couple with a flex connection 50 (e.g., cable) of the display system 10 via a plurality of bumps 52. Specifically, the plurality of bumps 52 may attach contact pads of the second RDL 54 implemented by a lower surface of the interposer 44 with contact pads on an upper surface of the flex connection 50. Thus, the second portion 32 of the display circuitry, implemented by the second backplane die 26, may couple on one side with the first portion 30 implemented by the first backplane die 24, and may further couple on another side with the display system 10 via the flex connection 50. The second RDL 54 may be included to relax pad pitch between the interposer 44 and the flex connection 50. As a result, the stacked chip assembly 20 may enable an entire surface of the interposer 44 to couple with the flex connection 50 in the display system 10.

In some implementations, the first backplane die 24 and the front plane die 22 may each have an equal footprint. For example, the first backplane die 24 and the front plane die 22 may have a same area, regardless of differences in thickness, with the first backplane die 24 and the front plane die 22 being aligned. This may enable a reduction of occupied area in the display system 10 (e.g., resulting in more space being available). The equal footprint (area) of the first backplane die 24 and the front plane die 22 may be attributed to WoW or CoW processing, where arrays of the first backplane die 24 and the front plane die 22 are singulated from a hybrid bonded stack. In FIGS. 2A-2B, the die stacks of the first backplane die 24 and the front plane die 22 can then be mounted onto a wafer including arrays of the second backplane die 26, followed by singulation of arrays of the 3-die stacks, which can then be processed and flip chip bonded onto the interposer 44 for further product integration, such as flip chip bonding to flex connection 50.

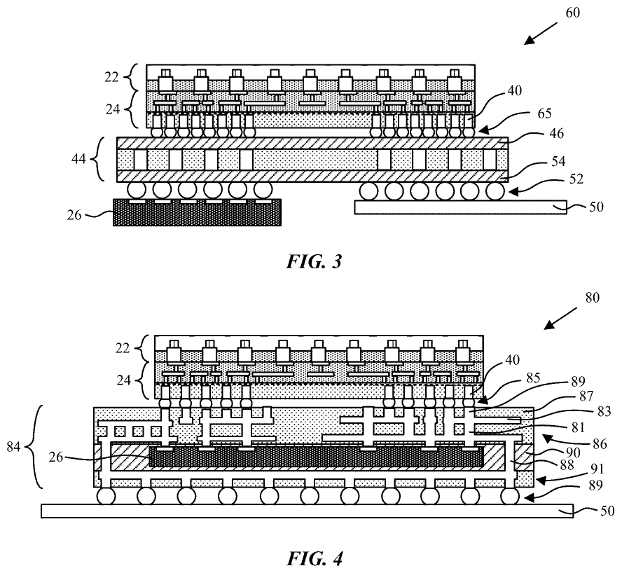

FIG. 3 is a cross-sectional side view of a second example of a stacked chip assembly 60. For example, the stacked chip assembly 60 could be one of the stacked chip assemblies 14, 16, or 18 implemented by the display system 10. Like the stacked chip assembly 20, the stacked chip assembly 60 may include the front plane die 22, the first backplane die 24, and the second backplane die 26 stacked vertically relative to one another. Also, the front plane die 22 may be coupled with the first backplane die 24 via hybrid bonding. Further, the first backplane die 24 may include the first plurality of TSVs 40 to enable electrical connections on both sides of the first backplane die 24.

The first backplane die 24 may couple with an interposer 44 via a plurality of micro bumps 65 (e.g., the die stack may be flipped onto the interposer 44). Specifically, the plurality of micro bumps 65 may attach contact pads on a lower surface of the first backplane die 24 with contact pads of the first RDL 46 implemented by an upper surface of the interposer 44. The first portion 30 implemented by the first backplane die 24 may couple with the interposer 44 via the plurality of micro bumps 65. The first RDL 46 may be included to relax pad pitch between the first backplane die 24 and the interposer 44. The interposer 44 may be stacked vertically relative to the front plane die 22 and the first backplane die 24 and may provide mechanical strength for the stacked chip assembly 60, such as to compensate for thinning of the first backplane die 24.

The interposer 44, in turn, may couple with each of the second backplane die 26 and the flex connection 50 via bumps 52. Thus, the second portion 32, coupled with the first portion 30, may further couple with the display system 10 via the flex connection 50. Specifically, the bumps 52 may attach contact pads of the second RDL 54 implemented by a lower surface of the interposer 44 with contact pads on an upper surface of the second backplane die 26 and contact pads on an upper surface of the flex connection 50. The second backplane die 26 may be stacked vertically relative to the front plane die 22, the first backplane die 24, and the interposer 44. The second RDL 54 may be included to relax pad pitch between the interposer 44 and the second backplane die 26 and relax pad pitch between the interposer 44 and the flex connection 50. As a result, the interposer 44 may be arranged between the first backplane die 24 and the second backplane die 26, avoiding the cost of forming TSVs in the second backplane die 26. The stacked chip assembly 60 may utilize one part of the lower surface of the interposer 44 to couple with the second backplane die 26, and another part of the lower surface of the interposer 44 to couple with the display system 10 via the flex connection 50.

FIG. 4 is a cross-sectional side view of a third example of a stacked chip assembly 80. For example, the stacked chip assembly 80 could be one of the stacked chip assemblies 14, 16, or 18 implemented by the display system 10. Like the stacked chip assembly 20, the stacked chip assembly 80 may include the front plane die 22, the first backplane die 24, and the second backplane die 26 stacked vertically relative to one another. Also, the front plane die 22 may be coupled with the first backplane die 24 via hybrid bonding. Further, the first backplane die 24 may include the first plurality of TSVs 40 to enable electrical connections on both sides of the first backplane die 24.

The first backplane die 24 may couple with an interposer 84 via a plurality of micro bumps 85 (e.g., the die stack may be flipped onto the interposer 84). Specifically, the plurality of micro bumps 85 may attach contact pads on a lower surface of the first backplane die 24 with contact pads of routing layer 86 implemented by an upper surface of the interposer 84. In FIG. 4, routing layer 86 may include a plurality of vias 81, routing lines 83, dielectric layers 87, and contact pads 89. The first portion 30 implemented by the first backplane die 24 may couple with the interposer 84 via the plurality of micro bumps 85. The interposer 84 may be stacked vertically relative to the front plane die 22 and the first backplane die 24 and may provide mechanical strength for the stacked chip assembly 80, such as to compensate for thinning of the first backplane die 24.

The interposer 84 may be one of a variety of types of interposers. In the example illustrated the second backplane die 26 is integrated within the interposer 84. For example, this can be accomplished by placing the second backplane die 26 into a cavity within a partially fabricated interposer 84, or molding around a placed second backplane die 26. In the embodiment illustrated, the routing layer 86 may be formed directly onto contact pads of the second backplane die 26. For example, this may be formed by placing the second backplane die 26 face down onto a carrier substrate, encapsulating the second backplane die 26 in a mold layer 90, followed by formation of optional routing layer 91 and through mold vias (TMVs) 88, and then formation of the routing layer 86 after removal of the carrier substrate.

The interposer 84 may include the mold layer 90 that encapsulates the second backplane die 26. The second backplane die 26 may be stacked vertically relative to the front plane die 22, the first backplane die 24, and the interposer 84. The mold layer 90 may include the plurality of TMVs 88 for coupling the routing layer 86 with the second backplane die 26. The mold layer 90, in turn, may couple with the flex connection 50 via the contact pads 89, and optional routing layer 91. As a result, the second portion 32, coupled with the first portion 30, may couple with the display system 10 via the flex connection 50. Specifically, the contact pads 89 may attach the plurality of TMVs 88 (or contact pads of the optional routing layer 91), implemented by a lower surface of the interposer 84, with contact pads on an upper surface of the flex connection 50. Thus, the stacked chip assembly 80 may enable an entire surface of the interposer 84 to couple with the flex connection 50 in the display system 10.

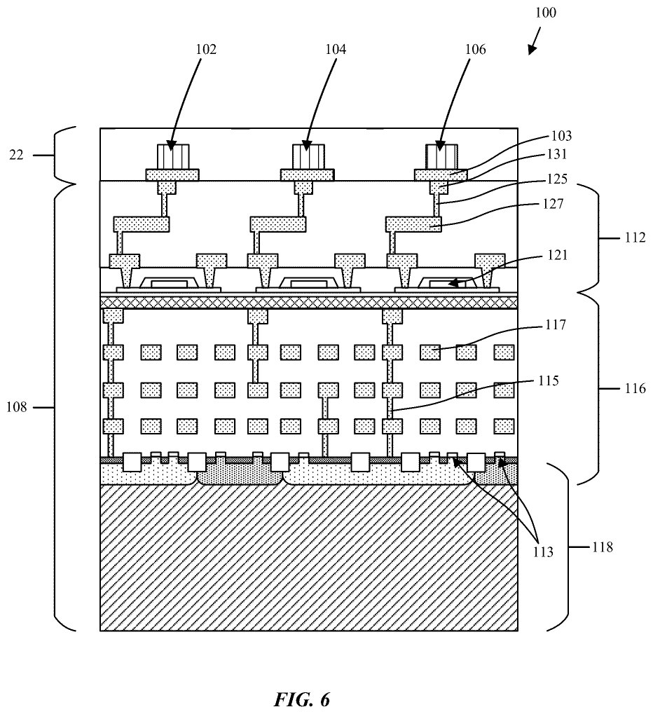

FIG. 6 is a cross-sectional side view of a fourth example of a stacked chip sub-assembly 100. For example, the stacked chip sub-assembly 100 could be integrated into one of the stacked chip assemblies 14, 16, or 18 implemented by the display system 10. Like the stacked chip assembly 20, the stacked chip sub-assembly 100 may include the front plane die 22 that includes the plurality of LEDs, such as LEDs 102, 104, and 106. For example, the plurality of LEDs may comprise OLEDs or micro LEDs. The stacked chip sub-assembly 100 may also include a backplane die 108 stacked vertically relative to the front plane die 22. The front plane die 22 may be coupled with the backplane die 108 via hybrid bonding. For example, the backplane die 108 could be like the first backplane die 24.

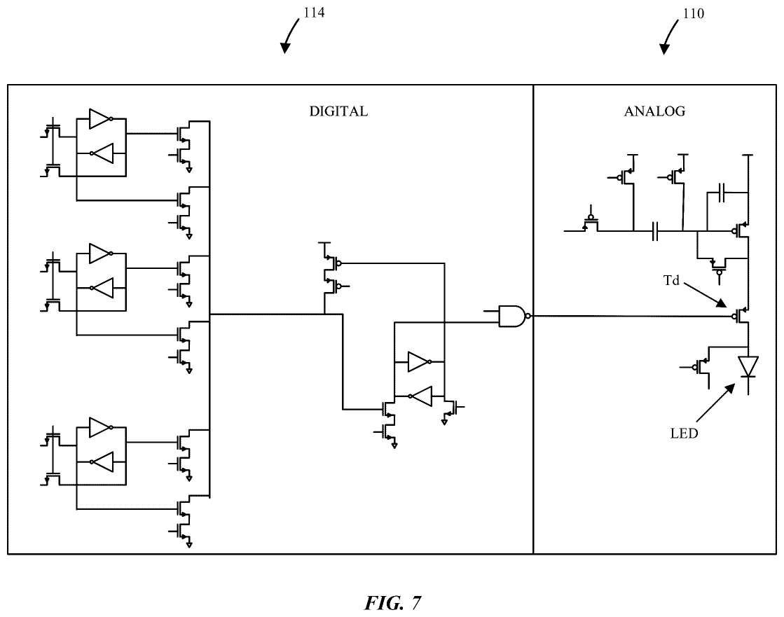

With additional reference to FIG. 7, the backplane die 108 may include display circuitry (e.g., pixel circuitry to drive the pixels in the front plane die 22, and memory cells for storing bits for the pixels) partitioned between analog circuitry 110 in a first layer 112 and digital circuitry 114 in a second layer 116. Thus, the backplane die 108 comprises a formation of both analog and digital circuitry in separate layers. For example, the first layer 112 may be formed directly over the second layer 116, which is formed on a substrate 118. The first layer 112 may comprise a TFT layer including TFTs inclusive of amorphous, polycrystalline, and/or oxide TFTs. The analog circuitry 110 of the first layer 112 may include transistors 121 coupled with the plurality of LEDs (e.g., 102, 104, 106) via electrical routing including vias 125, redistribution lines 127, and contact pads 131. For example, the analog circuitry 110 may include drive transistors (Td) coupled with the LEDs for driving the LEDs to produce light, such as a drive transistor (Td) coupled with an LED as shown in FIG. 7.

The second layer 116 may comprise a MOSFET layer. For example, the first layer 112 comprising the analog circuitry 110 (e.g., the TFT layer) may be deposited onto the second layer 116 comprising the digital circuitry 114 (e.g., the MOSFET layer) in the same backplane die. This may enable greater precision of the digital circuitry 114 and fitting more transistors in the stacked chip assembly 100 to increase pixel resolution in the display system 10 (e.g., a reduction in pitch between LEDs). The digital circuitry 114 of the MOSFET layer may include transistors 113 coupled with the analog circuitry 110 via electrical routing including vias 115 and redistribution lines 117. The digital circuitry 114 may include memory cells for the plurality of LEDs, for storing bits associated with the pixels represented by the LEDs, and logic for the plurality of LEDs, such as write enable logic for outputting the bits. In some implementations, the analog circuitry 110 may perform amplitude modulation (AM) for the plurality of LEDs, while the digital circuitry 114 performs pulse width modulation (PWM) for the plurality of LEDs. Thus, the display circuitry may be partitioned into multiple layers of a single backplane die to enable a higher resolution of the display system 10.

In some implementations, the backplane die 108 may be a single backplane in a stacked chip assembly. In some implementations, a second backplane die may be stacked vertically relative to the front plane die 22 and the backplane die 108. For example, the second backplane die 26, and in some cases an interposer, may be stacked below the front plane die 22 and the backplane die 108. The second backplane die could include additional portions of analog and/or digital circuitry coupled with the digital circuitry 114 in the second layer 116. For example, the second portion of digital circuitry could comprise digital transistors of the second portion 32.

As used herein, the term “circuitry” refers to an arrangement of electronic components (e.g., transistors, resistors, capacitors, and/or inductors) that is structured to implement one or more functions. For example, a circuit may include one or more transistors interconnected to form logic gates that collectively implement a logical function.

In utilizing the various aspects of the implementations, it would become apparent to one skilled in the art that combinations or variations of the above implementations are possible for stacked chip assemblies for display systems. Although the implementations have been described in language specific to structural features and/or methodological acts, it is to be understood that the appended claims are not necessarily limited to the specific features or acts described. The specific features and acts disclosed are instead to be understood as implementations of the claims useful for illustration.

What is claimed is:

1. A stacked chip assembly for a display system, comprising:
a front plane die including a plurality of light emitting diodes (LEDs);
a first backplane die stacked vertically relative to the front plane die, the first backplane die including a first portion of metal oxide semiconductor field effect transistor (MOSFET) display circuitry coupled with the plurality of LEDs; and
a second backplane die stacked vertically relative to the front plane die and the first backplane die, the second backplane die including a second portion of MOSFET display circuitry coupled with the first portion of MOSFET display circuitry.

2. The stacked chip assembly of claim 1, wherein the first backplane die is coupled with the front plane die via hybrid bonding.

3. The stacked chip assembly of claim 1, wherein the first backplane die includes a plurality of through silicon vias (TSVs) extending through the first backplane die.

4. The stacked chip assembly of claim 1, wherein the first portion of MOSFET display circuitry includes pixel circuitry to drive the plurality of LEDs.

5. The stacked chip assembly of claim 1, wherein the second portion of MOSFET display circuitry includes at least one of a timing controller (TCON) or a power management integrated circuit (PMIC).

6. The stacked chip assembly of claim 1, wherein the first backplane die and the front plane die each have an equal footprint.

7. The stacked chip assembly of claim 1, further comprising:
an interposer stacked vertically relative to the first backplane die and the second backplane die, the interposer including a redistribution layer (RDL) coupled with the second portion of MOSFET display circuitry.

8. The stacked chip assembly of claim 1, wherein the first backplane die and the second backplane die each include a plurality of TSVs extending therethrough.

9. The stacked chip assembly of claim 1, further comprising:
an interposer stacked vertically relative to the first backplane die and the second backplane die, wherein the second backplane die is coupled with the interposer via a plurality of micro bumps.

10. The stacked chip assembly of claim 1, further comprising:
an interposer stacked vertically relative to the first backplane die, wherein the interposer is arranged between the first backplane die and the second backplane die.

11. The stacked chip assembly of claim 1, further comprising:
an interposer stacked vertically relative to the first backplane die, wherein an upper surface of the interposer couples with the first backplane die, and wherein a lower surface of the interposer couples with the second backplane die and a flex connection.

12. The stacked chip assembly of claim 1, further comprising:
an interposer stacked vertically relative to the first backplane die, wherein the interposer includes a mold that encapsulates the second backplane die, the mold including a plurality of through mold vias (TMVs).

13. The stacked chip assembly of claim 1, further comprising:
an interposer stacked vertically relative to the first backplane die, wherein an entire surface of the interposer couples with a flex connection.

14. A display system, comprising:
a plurality of stacked chip assemblies, each stacked chip assembly including:
a front plane die including a plurality of light emitting diodes (LEDs);
a first backplane die stacked vertically relative to the front plane die, the first backplane die including a first portion of metal oxide semiconductor field effect transistor (MOSFET) display circuitry coupled with the plurality of LEDs; and
a second backplane die stacked vertically relative to the first backplane die and the front plane die, the second backplane die including a second portion of MOSFET display circuitry coupled with the first portion of MOSFET display circuitry.

15. The display system of claim 14, wherein the plurality of stacked chip assemblies are coupled with an eyepiece of a projector.

16. The display system of claim 14, further comprising:
an eyepiece including a lens, wherein the plurality of stacked chip assemblies emit light toward the eyepiece.

17. A stacked chip sub-assembly for a display system, comprising:
a front plane die including a plurality of light emitting diodes (LEDs); and
a backplane die stacked vertically relative to the front plane die, the backplane die including analog circuitry in a first layer and digital circuitry in a second layer, the analog circuitry including analog transistors coupled with the plurality of LEDs, and the digital circuitry including digital transistors coupled with the analog circuitry.

18. The stacked chip sub-assembly of claim 17, wherein the first layer is a thin film transistor (TFT) layer, and wherein the second layer is a metal oxide semiconductor field effect transistor (MOSFET) layer.

19. The stacked chip sub-assembly of claim 17, wherein the analog circuitry includes a drive transistor coupled with an LED of the plurality of LEDs, and wherein the digital circuitry includes a memory cell for the LED.

20. The stacked chip sub-assembly of claim 17, further comprising:
a second backplane die stacked vertically relative to the front plane die and the backplane die, the second backplane die including a second portion of digital circuitry coupled with the digital circuitry in the second layer.
